(19) United States
(12) Patent Application Publication
(10) Pub. No.: US 2022/0311437 A1
(43) Pub. Date: Sep. 29, 2022

(54) ELECTRONIC CIRCUIT

(71) Applicants: SONY SEMICONDUCTOR SOLUTIONS CORPORATION, KANAGAWA (JP); SONY GROUP CORPORATION, TOKYO (JP)

(72) Inventor: YUKI YAGISHITA, KANAGAWA (JP)

(21) Appl. No.: 17/596,527

(22) PCT Filed: Mar. 17, 2020
(86) PCT No.: PCT/JP2020/011590

§ 371 Date: Dec. 13, 2021

(30) Foreign Application Priority Data
Jun. 21, 2019 (JP) 2019-115056

(51) Int. Cl. H03K 17/693; H03K 17/567

(52) U.S. Cl. CPC H03K 17/693; H03K 17/567

(57) ABSTRACT

To suppress the off-leakage current in a switch circuit when the switch circuit is controlled to be in an OFF state.

First and second path switches are switch circuits connected in series. The first and second path switches are controlled to be in either an ON state of an OFF state at the same time. When the first and second path switches are controlled to be in the OFF state, the voltage supply circuit supplies the same voltage to the connection portion of the first and second path switches and the input portion of the first path switch. In this way, the same voltage is supplied to both ends of the first path switch.

### TECHNICAL FIELD

The present technology relates to electronic circuits. More specifically, the present invention relates to an electronic circuit having a switch circuit on a path for transmitting a signal.

### BACKGROUND ART

The switch circuit is used in many analog signal processing circuits as an analog signal selection circuit. This switch circuit is required to have no electrical connection in the OFF (disconnected) state, but actually, an off-leakage current may flow. Therefore, in order to reduce the off-leakage current of the switch circuit, for example, a circuit has been proposed in which two switch circuits are connected in series and biased so that the node between the two switch circuits has a constant potential difference with the input voltage of the switch circuit (see, for example, PTL 1).

### CITATION LIST

### Patent Literature

### [PTL 1]

JP 2005-268901 A

### SUMMARY

### Technical Problem

In the above-mentioned conventional technique, a switch circuit is used to realize the sample and hold function, and the switch circuit is biased so that the off-leakage current is kept constant in order to reduce the voltage dependence of the leak current of the input node. However, in this conventional technique, since a constant potential difference is generated in the transistor, it is not possible to prevent the leakage current from flowing.

The present technology has been made in view of this situation, and an object thereof is to suppress the off-leakage current in a switch circuit.

### Solution to Problem

The present technology has been made to solve the above-mentioned problems, and a first aspect thereof provides an electronic circuit including: first and second path switches connected in series and controlled to be in either an ON state or an OFF state at the same time, and a voltage supply circuit that supplies the same voltage to a connection portion of the first and second path switches and an input portion of the first path switch when the first and second path switches are controlled to be in the OFF state. This has the effect that the off-leakage current of the first path switch is suppressed.

Further, in the first aspect, the voltage supply circuit may include a supply switch for switching whether or not to supply the same voltage to the connection portion of the first and second path switches and the input portion of the first path switch. This has the effect that whether or not to supply the voltage is switched according to the state of the first and second path switches.

Further, in the first aspect, each of the first and second path switches and the supply switch may be configured with a CMOS transistor in which a pMOS transistor and an nMOS transistor are connected in parallel. This has the effect that an input voltage is appropriately dealt with even if the input voltage is high or low.

Further, in this first aspect, each of the first and second path switches and the supply switch may be configured with a pMOS transistor. This has the effect that the amount of hardware under the condition that a high voltage is not input in the ON state is reduced.

Further, in this first aspect, each of the first and second path switches and the supply switch may be configured with an nMOS transistor. This has the effect that the amount of hardware under the condition that a low voltage is not input in the ON state is reduced.

Further, in the first aspect, the voltage supply circuit may include a voltage generation circuit that generates the same voltage. This has the effect that the same voltage is applied to both ends of the first path switch.

Further, in this first aspect, the electronic circuit may further include a high-pass filter having a capacitor connected in series between an input signal and the first and second path switches and a resistor connected in parallel to the input signal, and the voltage supply circuit may supply the same voltage from the voltage generation circuit to the input portion of the first path switch via the resistor. This has the effect that, when the input signal is an AC signal, the same voltage is applied to both ends of the first path switch via the resistor of the high-pass filter.

Further, in the first aspect, the voltage supply circuit may include a voltage buffer that generates an output signal having a voltage equal to that of the input signal, and the input signal may be supplied to the input portion of the first path switch, and an output signal of the voltage buffer may be supplied to the connection portion of the first and second path switches when the first and second path switches are controlled to be in the OFF state. This has the effect that, when the input signal is a DC signal, the same voltage is applied to both ends of the first path switch. In this case, the voltage buffer may be configured with a voltage follower circuit in which an inverting input and an output of an operational amplifier are connected.

Further, in the first aspect, the first and second path switches may include a pair of paths that handles differential signals having different phases, and the voltage supply circuit may supply the same voltage to the connection portion of the first and second path switches and the input portion of the first path switch in each of the pair of paths when the first and second path switches are controlled to be in the OFF state. This has the effect that, when the input signal is a differential signal, the same voltage is applied to both ends of the first path switch.

Further, in the first aspect, the voltage supply circuit may include a resistance element that divides the differential signals and a voltage buffer that generates an output signal having the same voltage as the signal input via the resistance element, and in each of the pair of paths, one of the differential signals may be supplied to the input portion of the first path switch, and the output signal of the voltage buffer may be supplied to the connection portion of the first and second path switches when the first and second path switches are controlled to be in the OFF state. This has the effect that a voltage buffer is shared in the differential signal.

### BRIEF DESCRIPTION OF DRAWINGS

FIG. 1 is a diagram showing a configuration example of an electronic circuit according to a first embodiment of the present technology.

FIG. 2 is a diagram showing a first configuration example of a switch circuit according to the embodiment of the present technology.

FIG. 3 is a diagram showing a second configuration example of a switch circuit according to the embodiment of the present technology.

FIG. 4 is a diagram showing a third configuration example of a switch circuit according to the embodiment of the present technology.

FIG. 5 is a diagram showing a configuration example of an electronic circuit according to a second embodiment of the present technology.

FIG. 6 is a diagram showing a configuration example of an electronic circuit according to a third embodiment of the present technology.

FIG. 7 is a diagram showing a first configuration example of an electronic circuit according to a fourth embodiment of the present technology.

FIG. 8 is a diagram showing a second configuration example of an electronic circuit according to a fourth embodiment of the present technology.

### DESCRIPTION OF EMBODIMENTS

Hereinafter, modes for implementing the present technique (hereinafter referred to as embodiments) will be described. The description will be made in the following order.

1. First embodiment (Example where input signal is AC signal)
2. Second embodiment (Example where input signal is differential AC signal)
3. Third embodiment (Example where input signal is DC signal)
4. Fourth embodiment (Example where input signal is differential DC signal)

### 1. First Embodiment

[Electronic Circuit]

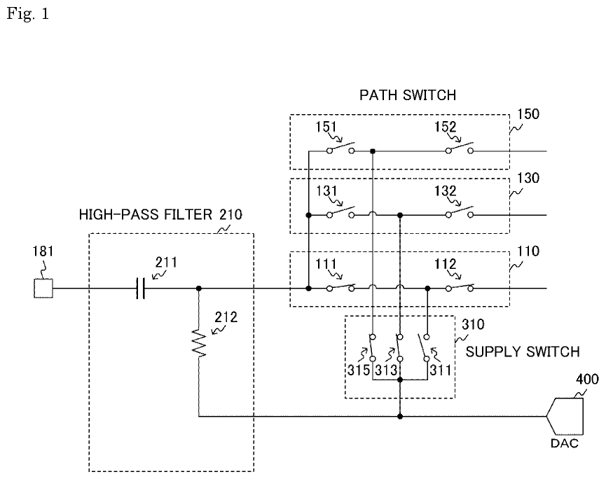

FIG. 1 is a diagram showing a configuration example of an electronic circuit according to a first embodiment of the present technology.

This electronic circuit is a circuit that outputs an AC signal input from an input terminal 181 to any of a plurality of paths. This electronic circuit includes a high-pass filter 210, path switches 110, 130 and 150, a supply switch 310, and a digital-to-analog conversion circuit 400.

The high-pass filter 210 is a filter that allows only the AC component of the signal input from the input terminal 181 to pass through. The high-pass filter 210 is a CR circuit including a capacitor (C: capacitor) 211 and a resistor (R: Resistance) 212. The capacitor 211 is connected in series between the input signal and the path switches 110, 130 and 150. The resistor 212 is connected in parallel with the input signal.

The cutoff frequency of the high-pass filter 210 can be determined from the constants of the capacitor 211 and the resistor 212. For example, when the capacitor 211 is 15 nF (farad) and the resistor 212 is 100 MΩ (ohm), the cutoff frequency fc is calculated by the following equation and is 0.1 Hz.

fc=1/(2πRC)

For example, assuming a biological signal such as an electroencephalogram or an electrocardiogram as an input signal, since it is several Hz to several tens of Hz, a high-pass filter having a low cutoff frequency such as 0.1 Hz is used. In this case, since the resistance value of the resistor used becomes large, a large voltage is generated even for a small leakage current. Therefore, it becomes more important to suppress the leak current itself.

The path switches 110, 130 and 150 are switch circuits on a plurality of signal paths at the output of the high-pass filter 210. In this example, three paths are shown. Although the output side of each path is not shown here, the path switches are connected to an amplifier or other circuits to supply signals.

The path switches 110, 130 and 150 of each path are configured by connecting two switch circuits 111 and 112, 131 and 132, 151, and 152 in series, respectively. The switch circuits 111, 131, and 151 are examples of a first path switch described in the claims. Further, the switch circuits 112, 132 and 152 are examples of a second path switch described in the claims.

The switch circuits 111 and 112 are controlled so as to be in either an ON (energized) state or an OFF (disconnected) state at the same time. That is, if the switch circuit 111 is in the ON state, the switch circuit 112 is also in the ON state, and if the switch circuit 111 is in the OFF state, the switch circuit 112 is also in the OFF state. The relationship between the switch circuits 131 and 132 and the relationship between the switch circuits 151 and 152 are the same.

Therefore, when a signal is passed through the corresponding path, all the switch circuits on the path are turned on, and when no signal is passed through the corresponding path, all the switch circuits on the path are turned off. Detailed description of the control for transitioning these switch circuits to the ON or OFF state will be omitted here.

The supply switch 310 is a switch for switching whether or not to supply a predetermined voltage to the switch circuits 111, 131, and 151. The supply switch 310 includes switch circuits 311, 313, and 315 corresponding to the switch circuits 111, 131, and 151, and switches whether or not to supply a predetermined voltage to each of them.

That is, for the path that does not pass a signal among the three paths, both ends of the switch circuit on the input side are set to have the same voltage. For example, when the signal is not passed through the path of the path switch 110, the switch circuits 111 and 112 are turned off. At this time, the switch circuit 311 is turned on, and the connection portion of the switch circuits 111 and 112 and the input portion of the switch circuit 111 are connected via the resistor 212. In this example, since an AC signal is assumed as an input signal, no direct current flows through the resistor 212, and no voltage drop occurs in the resistor 212. Therefore, the voltages at both ends of the switch circuit 111 in this case are equal. Therefore, no leakage current is generated in the switch circuit 111.

The digital-to-analog conversion circuit 400 is a circuit for converting a digital signal into an analog signal. Here, the digital-to-analog conversion circuit 400 is used to generate a predetermined reference voltage Vref. The digital-to-analog conversion circuit 400 is an example of a voltage generation circuit described in the claims.

The reference voltage Vref output from the digital-to-analog conversion circuit 400 is supplied to one set of ends of the switch circuits 311, 313 and 315 of the supply switch 310 and one set of ends of the resistor 212 of the high-pass filter 210. Therefore, the DC component of the output of the high-pass filter 210 has the same voltage as the reference voltage Vref.

On the other hand, the switch circuit of the path switch 110, 130 or 150 of the path through which the signal does not pass is turned off, and the corresponding switch circuit 311 or 313 or 315 is turned on. At this time, the node between the two switch circuits in the path switches 110, 130 or 150 corresponding to the switch circuits 311, 313 or 315 in the ON state has the reference voltage Vref. Therefore, both ends of the switch circuit 111, 131, or 151 that are in the OFF state have the same voltage (reference voltage Vref), and the leakage current does not occur as described above.

Even when the OFF resistance Roff of the switch circuit 111 is assumed to be 1 GΩ, if the potential difference Voff at both ends of the OFF state is zero, it can be seen that the leak current Ioff at that time becomes zero from the following equation.

Ioff=Voff/Roff

[Switch Circuit]

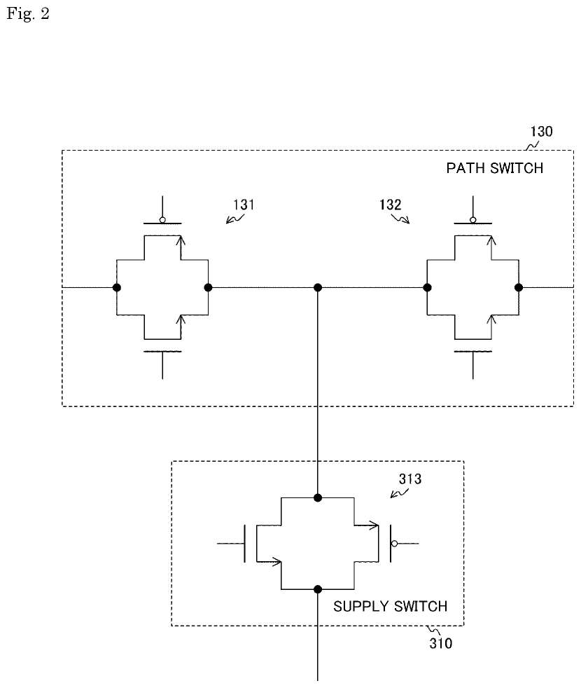

FIG. 2 is a diagram showing a first configuration example of a switch circuit according to the embodiment of the present technology.

In this first configuration example, the switch circuits 111, 112, 131, 132, 151 and 152 of the path switches 110, 130 and 150 and the switch circuits 311, 313 and 315 of the supply switch 310 are configured with a CMOS (Complementary MOS) transistor in which an nMOS (n-type MOS (Metal-Oxide-Semiconductor)) transistor and a pMOS (p-type MOS) transistor are connected in parallel. In the drawing, the switch circuits 131 and 132 of the path switch 130 and the switch circuit 313 of the supply switch 310 are shown as typical examples.

When a high voltage is input to the nMOS transistor in the ON state, the gate-source voltage Vgs becomes smaller than the threshold voltage Vth, and the ON-resistance may increase. On the other hand, when a low voltage is input to the pMOS transistor in the ON state, the gate-source voltage Vgs becomes smaller than the threshold voltage Vth, and the ON resistance may increase. Therefore, by configuring the switch circuit with CMOS transistors as in this first configuration example, since the nMOS transistors and pMOS transistors connected in parallel operate complementarily, it is possible to appropriately deal with an input voltage even if the input voltage is high or low.

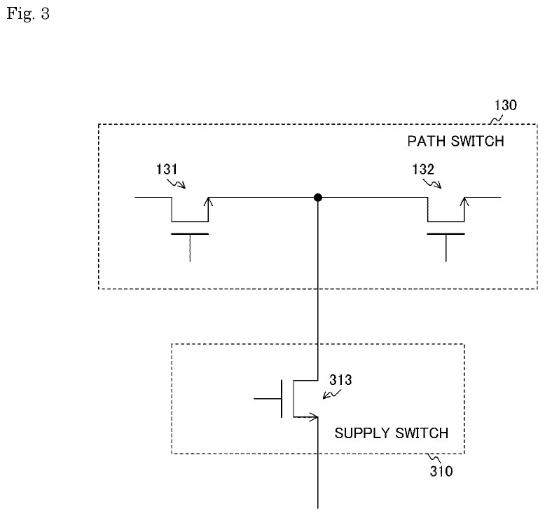

FIG. 3 is a diagram showing a second configuration example of the switch circuit according to the embodiment of the present technology.

In this second configuration example, the switch circuits 111, 112, 131, 132, 151 and 152 of the path switches 110, 130 and 150 and the switch circuits 311, 313 and 315 of the supply switch 310 are configured with nMOS transistors.

As described above, by configuring the switch circuits with CMOS transistors, it is possible to appropriately deal with an input voltage even if the input voltage is a high or low. However, since two transistors are required for one switch circuit, the amount of hardware increases. On the other hand, in the usage mode in which a high voltage is not input in the ON state, the amount of hardware can be reduced as compared with the first configuration example by configuring the switch circuit with nMOS transistors as in the second configuration example.

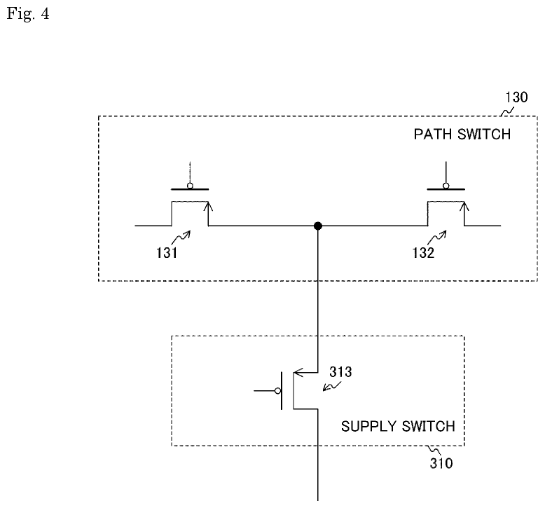

FIG. 4 is a diagram showing a third configuration example of the switch circuit according to the embodiment of the present technology.

In this third configuration example, the switch circuits 111, 112, 131, 132, 151 and 152 of the path switches 110, 130 and 150 and the switch circuits 311, 313 and 315 of the supply switch 310 are configured with pMOS transistors.

In the usage mode in which a low voltage is not input in the ON state, the amount of hardware can be reduced as compared with the first configuration example by configuring the switch circuit with pMOS transistors as in the third configuration example.

As described above, according to the first embodiment of the present technology, the off-leakage current of the switch circuit can be suppressed by supplying the same voltage to both ends of the switch circuit 111, 131 or 151 of the path through which the signal does not pass.

### 2. Second Embodiment

[Electronic Circuit]

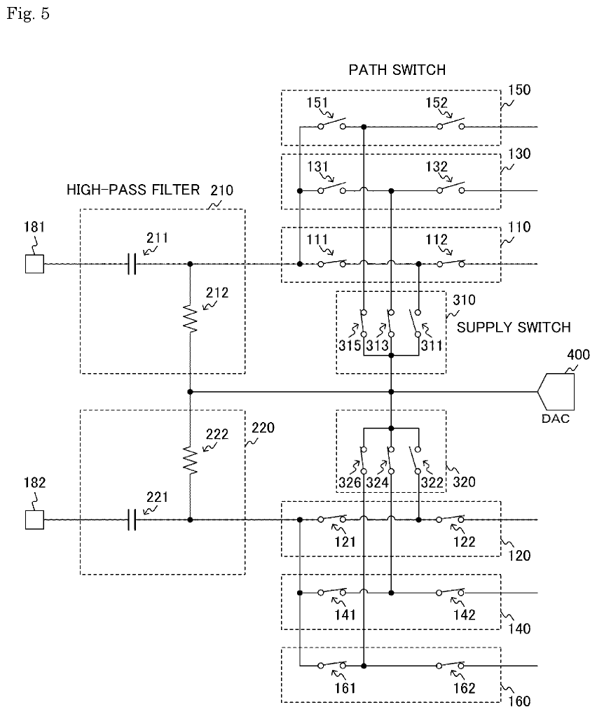

FIG. 5 is a diagram showing a configuration example of an electronic circuit according to a second embodiment of the present technology.

In this second embodiment, it is assumed that AC differential signals are input from the input terminals 181 and 182. The electronic circuit in this second embodiment includes high-pass filters 210 and 220, path switches 110, 120, 130, 140, 150 and 160, supply switches 310 and 320, and a digital-to-analog conversion circuit 400.

The high-pass filter 210 is a filter that allows only the AC component of the signal input from the input terminal 181 to pass through, as in the first embodiment described above. The high-pass filter 220 is a filter that allows only the AC component of the signal input from the input terminal 182 to pass through, and is a CR circuit including a capacitor 221 and a resistor 222. One set of ends of resistors 212 and 222 of the high-pass filters 210 and 220 are commonly connected to the output of the digital-to-analog conversion circuit 400.

The path switches 110, 130 and 150 are switch circuits on a plurality of signal paths at the output of the high-pass filter 210, as in the first embodiment described above. Further, the path switches 120, 140 and 160 are switch circuits on a plurality of signal paths at the output of the high-pass filter 220. Since the internal configurations of the path switches 120, 140 and 160 are the same as those of the path switches 110, 130 and 150 described above, detailed description thereof will be omitted.

The supply switch 310 is a switch for switching whether or not to supply a predetermined voltage to the switch circuits 111, 131, and 151, as in the first embodiment described above. Further, the supply switch 320 is a switch for switching whether or not to supply a predetermined voltage to the switch circuits 121, 141 and 161. The supply switch 320 includes switch circuits 322, 324, and 326 corresponding to the switch circuits 121, 141, and 161 and switches whether or not to supply a predetermined voltage to each of the switch circuits 322, 324, and 326.

The digital-to-analog conversion circuit 400 is a circuit that generates a predetermined reference voltage Vref, as in the first embodiment described above. The reference voltage Vref output from the digital-to-analog conversion circuit 400 is supplied to one set of ends of the switch circuits 311, 313 and 315 of the supply switch 310, one set of ends of the switch circuits 322, 324 and 326 of the supply switch 320, and one set of ends of the resistor 212 of the resistance of the high-pass filter 210 and the resistor 222 of the high-pass filter 220. Therefore, the DC component of the output of the high-pass filters 210 and 220 has the same voltage as the reference voltage Vref.

On the other hand, both ends of the switch circuits 111, 121, 131, 141, 151, or 161 that are in the OFF state have the same voltage (reference voltage Vref), and no leakage current occurs as described above.

As described above, according to the second embodiment of the present technology, even in the electronic circuit that receives a differential AC signal as an input, by supplying the same voltage to both ends of the switch circuits 111, 121, 131, 141, 151 or 161 of the path that does not pass the signal, the off-leakage current of the switch circuit can be suppressed.

### 3. Third Embodiment

[Electronic Circuit]

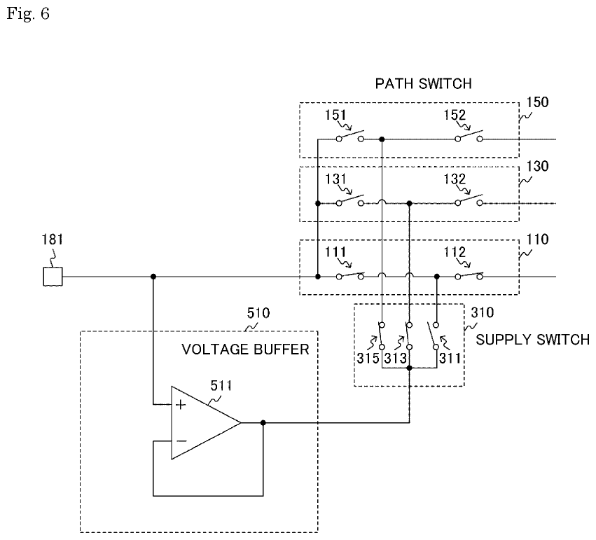

FIG. 6 is a diagram showing a configuration example of an electronic circuit according to a third embodiment of the present technology.

In this third embodiment, it is assumed that a DC signal is input from the input terminal 181 as an input signal. The electronic circuit in this third embodiment includes a voltage buffer 510, path switches 110, 130 and 150, and a supply switch 310.

The voltage buffer 510 buffers the voltage of the input signal from the input terminal 181 and outputs the buffered voltage to the output side. In this case, the voltage on the input side and the voltage on the output side are equal. The voltage buffer 510 is configured as a voltage follower circuit in which the inverting input and output of an operational amplifier 511 are connected. The output voltage from the voltage buffer 510 is supplied to one set of ends of the switch circuits 311, 313, and 315 of the supply switch 310.

The path switches 110, 130 and 150 are switch circuits on a plurality of signal paths to which the input signal from input terminal 181 is supplied. Similarly to the first embodiment described above, the path switches 110, 130 and 150 of the respective paths are configured by connecting two switch circuits 111 and 112, 131 and 132, 151 and 152 in series, respectively.

The supply switch 310 is a switch for switching whether or not to supply a predetermined voltage to the switch circuits 111, 131, and 151, as in the first embodiment described above. As described above, the output voltage from the voltage buffer 510 is supplied to one set of ends of the switch circuits 311, 313, and 315 of the supply switch 310. Therefore, both ends of the switch circuit 111, 131, or 151 that are in the OFF state have the same voltage (input signal from the input terminal 181), and no leakage current occurs.

As described above, according to the third embodiment of the present technology, even in the electronic circuit that receives a DC signal as an input, by supplying the same voltage to both ends of the switch circuit 111, 131 or 151 of the path that does not pass the signal even, the off-leakage current of the switch circuit can be suppressed.

### 4. Fourth Embodiment

[First Configuration of Electronic Circuit]

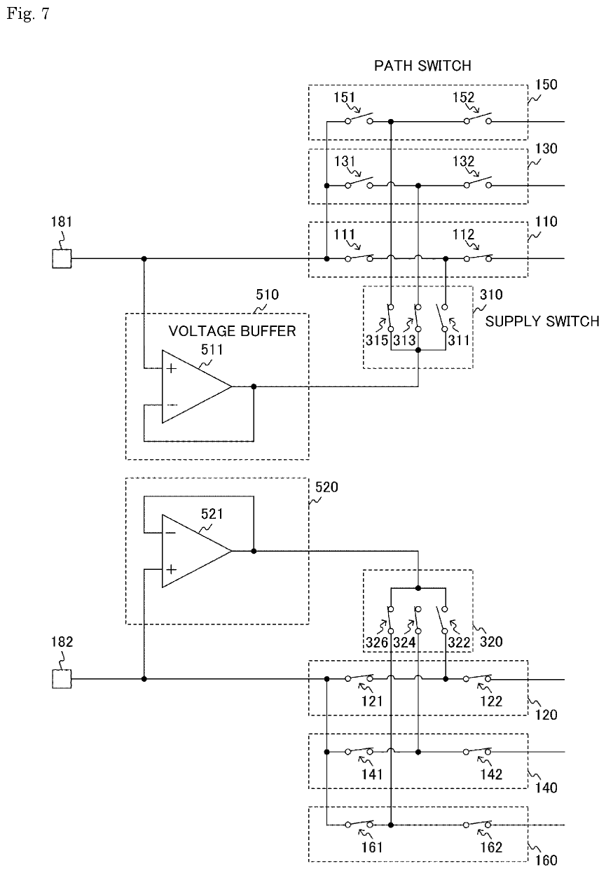

FIG. 7 is a diagram showing a first configuration example of an electronic circuit according to a fourth embodiment of the present technology.

In this fourth embodiment, it is assumed that a DC differential signal is input from the input terminals 181 and 182. In this first configuration example, the electronic circuits of the third embodiment described above are symmetrically provided according to differential signals. Since each operation is the same as that of the third embodiment described above, detailed description thereof will be omitted.

[Second Configuration of Electronic Circuit]

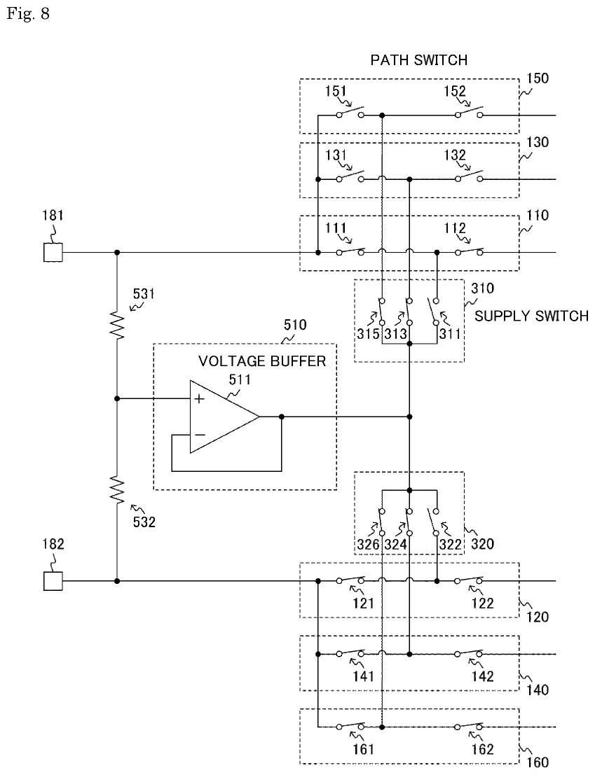

FIG. 8 is a diagram showing a second configuration example of the electronic circuit according to the fourth embodiment of the present technology.

In this second configuration example, as compared with the first configuration example, only one voltage buffer 510 is provided and connected to the input terminals 181 and 182 via resistors 531 and 532. In this case, the average value of the input terminals 181 and 182 is input as the common voltage to the input of the voltage buffer 510. Therefore, one voltage buffer 510 can be shared in the differential signal.

As described above, according to the fourth embodiment of the present technology, even in the electronic circuit that receives a differential DC signal as an input, by supplying the same voltage to both ends of the switch circuits 111, 121, 131, 141, 151 or 161 of the path that does not pass the signal, the off-leakage current of the switch circuit can be suppressed.

The embodiments described above each describe an example for embodying the present technology, and matters in the embodiments and matters specifying the invention in the claims have correspondence relationships. Similarly, the matters specifying the invention in the claims and the matters in the embodiments of the present technique having the same name have a corresponding relationship with each other. However, the present technique is not limited to the embodiments and can be embodied by applying various modifications to the embodiments without departing from the gist thereof.

In addition, the effects described in the present specification are merely examples and are not intended as limiting, and other effects may be obtained.

Further, the present technique can have the following configurations.

(1) An electronic circuit including: first and second path switches connected in series and controlled to be in either an ON state or an OFF state at the same time, and a voltage supply circuit that supplies the same voltage to a connection portion of the first and second path switches and an input portion of the first path switch when the first and second path switches are controlled to be in the OFF state.

(2) The electronic circuit according to (1), wherein the voltage supply circuit includes a supply switch for switching whether or not to supply the same voltage to the connection portion of the first and second path switches and the input portion of the first path switch.

(3) The electronic circuit according to (2), wherein each of the first and second path switches and the supply switch is configured with a CMOS transistor in which a pMOS transistor and an nMOS transistor are connected in parallel.

(4) The electronic circuit according to (2), wherein each of the first and second path switches and the supply switch is configured with a pMOS transistor.

(5) The electronic circuit according to (2), wherein each of the first and second path switches and the supply switch is configured with an nMOS transistor.

(6) The electronic circuit according to any one of (1) to (5), wherein the voltage supply circuit includes a voltage generation circuit that generates the same voltage.

(7) The electronic circuit according to (6), further including: a high-pass filter having a capacitor connected in series between an input signal and the first and second path switches and a resistor connected in parallel to the input signal, wherein the voltage supply circuit supplies the same voltage from the voltage generation circuit to the input portion of the first path switch via the resistor.

(8) The electronic circuit according to any one of (1) to (5), wherein the voltage supply circuit includes a voltage buffer that generates an output signal having a voltage equal to that of the input signal, and the input signal is supplied to the input portion of the first path switch, and an output signal of the voltage buffer is supplied to the connection portion of the first and second path switches when the first and second path switches are controlled to be in the OFF state.

(9) The electronic circuit according to (8), wherein the voltage buffer is configured with a voltage follower circuit in which an inverting input and an output of an operational amplifier are connected.

(10) The electronic circuit according to any one of (1) to (5), wherein the first and second path switches include a pair of paths that handles differential signals having different phases, and the voltage supply circuit supplies the same voltage to the connection portion of the first and second path switches and the input portion of the first path switch in each of the pair of paths when the first and second path switches are controlled to be in the OFF state.

(11) The electronic circuit according to (10), wherein the voltage supply circuit includes a resistance element that divides the differential signals and a voltage buffer that generates an output signal having the same voltage as the signal input via the resistance element, and in each of the pair of paths, one of the differential signals is supplied to the input portion of the first path switch, and the output signal of the voltage buffer is supplied to the connection portion of the first and second path switches when the first and second path switches are controlled to be in the OFF state.

### REFERENCE SIGNS LIST

110, 120, 130, 140, 150, 160 Path switch
111, 112, 121, 122, 131, 132, 141, 142, 151, 152, 161, 162 Switch circuit
181, 182 Input terminal
210, 220 High-pass filter
211, 221 Capacitor
212, 222 Resistor
310, 320 Supply switch
311 313, 315, 322, 324, 326 Switch circuit
400 Digital-to-analog conversion circuit
510, 520 Voltage buffer
511, 521 Operational amplifier
531, 532 Resistor

1. An electronic circuit comprising:
first and second path switches connected in series and controlled to be in either an ON state or an OFF state at the same time, and
a voltage supply circuit that supplies the same voltage to a connection portion of the first and second path switches and an input portion of the first path switch when the first and second path switches are controlled to be in the OFF state.

2. The electronic circuit according to claim 1, wherein
the voltage supply circuit includes a supply switch for switching whether or not to supply the same voltage to the connection portion of the first and second path switches and the input portion of the first path switch.

3. The electronic circuit according to claim 2, wherein
each of the first and second path switches and the supply switch is configured with a CMOS transistor in which a pMOS transistor and an nMOS transistor are connected in parallel.

4. The electronic circuit according to claim 2, wherein
each of the first and second path switches and the supply switch is configured with a pMOS transistor.

5. The electronic circuit according to claim 2, wherein
each of the first and second path switches and the supply switch is configured with an nMOS transistor.

6. The electronic circuit according to claim 1, wherein
the voltage supply circuit includes a voltage generation circuit that generates the same voltage.

7. The electronic circuit according to claim 6, further comprising:
a high-pass filter having a capacitor connected in series between an input signal and the first and second path switches and a resistor connected in parallel to the input signal, wherein
the voltage supply circuit supplies the same voltage from the voltage generation circuit to the input portion of the first path switch via the resistor.

8. The electronic circuit according to claim 1, wherein the voltage supply circuit includes a voltage buffer that generates an output signal having a voltage equal to that of the input signal, and
the input signal is supplied to the input portion of the first path switch, and an output signal of the voltage buffer is supplied to the connection portion of the first and second path switches when the first and second path switches are controlled to be in the OFF state.

9. The electronic circuit according to claim 8, wherein
the voltage buffer is configured with a voltage follower circuit in which an inverting input and an output of an operational amplifier are connected.

10. The electronic circuit according to claim 1, wherein
the first and second path switches include a pair of paths that handles differential signals having different phases, and
the voltage supply circuit supplies the same voltage to the connection portion of the first and second path switches and the input portion of the first path switch in each of the pair of paths when the first and second path switches are controlled to be in the OFF state.

11. The electronic circuit according to claim 10, wherein the voltage supply circuit includes a resistance element that divides the differential signals and a voltage buffer that generates an output signal having the same voltage as the signal input via the resistance element, and
in each of the pair of paths, one of the differential signals is supplied to the input portion of the first path switch, and the output signal of the voltage buffer is supplied to the connection portion of the first and second path switches when the first and second path switches are controlled to be in the OFF state.
